(19) United States
(12) Patent Application Publication
(10) Pub. No.: US 2014/0116335 A1
(43) Pub. Date: May 1, 2014

(54) UV Irradiation Apparatus with Cleaning Mechanism and Method for Cleaning UV Irradiation Apparatus

(71) Applicant: ASM IP HOLDING B.V., Almere (NL)

(72) Inventors: Naoto Tsuji, Tokyo (JP); Yasushi Fukasawa, Sagamahira-shi (JP)

(73) Assignee: ASM IP Holding B.V., Almere (NL)

(21) Appl. No.: 13/665,366

(22) Filed: Oct. 31, 2012

(51) Int. Cl. H01L 21/02

(52) U.S. Cl. CPC H01L 21/02
USPC 118/620; 134/1.1

(57) ABSTRACT

A UV irradiation apparatus for processing a semiconductor substrate includes: a UV lamp unit; a reaction chamber disposed under the UV lamp unit; a gas ring with nozzles serving as a first electrode between the UV lamp unit and the reaction chamber; a transmission window supported by the gas ring; an RF shield which covers a surface of the transmission window facing the UV lamp unit; a second electrode disposed in the reaction chamber for generating a plasma between the first and second electrodes; and an RF power source for supplying RF power to one of the first or second electrode.

### BACKGROUND

1. Field of the Invention

The present invention generally relates to a UV irradiation apparatus for processing a substrate such as a semiconductor wafer using UV light and a method for cleaning the UV irradiation apparatus, particularly, cleaning a transmission window and an inner wall of the apparatus.

2. Description of the Related Art

In general, UV irradiation apparatuses have been used for the quality modification of various processing targets via ultraviolet light and preparation of substances using photochemical reaction. With the recent trend for higher integration of devices, which requires finer wiring designs and multi-layer wiring structures, it is essential to reduce the inter-layer volume to make the devices operate faster while consuming less power. Low-k (low dielectric constant film) materials are used to reduce the inter-layer volume, but these materials not only lower the dielectric constant, but they also reduce the mechanical strength (EM: elastic modulus) and are vulnerable to stress received after the CMP, wire bonding, and packaging post-processes. One way to improve the aforementioned problems is to irradiate UV to cure the low-k material and thereby improve its mechanical strength (refer to U.S. Pat. No. 6,759,098 and U.S. Pat. No. 6,296,909, for example).

UV irradiation causes the low-k material to shrink and cure, allowing its mechanical strength (EM) to be improved by 50 to 200%. Also, porogen materials introduced to the film can be decomposed and/or removed by means of UV irradiation (or heating, plasma, or electron beam) to lower the dielectric constant of the film while curing the film at the same time (refer to U.S. Pat. No. 6,583,048, U.S. Pat. No. 6,846,515 and U.S. Pat. No. 7,098,149, for example).

Irradiating this optical energy onto the processing target or into the reaction space requires the UV lamp and reaction space to be partitioned, for the following reasons, among others: 1) pressure and ambient gas in the reaction space must be controlled, 2) generated gas would contaminate the UV lamp; and 3) generated gas must be exhausted safely. For this partition plate, normally a UV light transmission window made of synthetic quartz has been used that allows optical energy to be transmitted therethrough.

### SUMMARY

However, UV light generating high energy presents problems, such as a lower transmission ratio that is likely to occur due to the material of the light transmission window and the attachment of deposits on the window material, and a shorter maintenance cycle (the light transmission window must be cleaned or replaced frequently or at very short intervals) in curing processes where a large amount of outgas (decomposition gas that produces film on the irradiation target) generates.

For example, one cleaning method is to introduce O₂ into the reaction space and irradiate UV to generate ozone, and use the generated ozone to remove deposits. In curing processes where a large amount of outgas generates, however, the cleaning time becomes longer with this method and therefore a more efficient method is desired.

Another method is to use a radical-generating system installed outside of the UV irradiation chamber to generate radical species and then introduce these radical species into the UV irradiation chamber from outside the UV irradiation chamber. However, this method requires a large, expensive apparatus and thus, an inexpensive, space-saving method is desired.

Any discussion of problems and solutions involved in the related art such as those discussed above has been included in this disclosure solely for the purposes of providing a context for the present invention, and should not be taken as an admission that any or all of the discussion were known at the time the invention was made.

In an embodiment of the present invention, a step to clean the UV transmission window and inner walls of the UV irradiation chamber is provided, as a cleaning method for UV irradiation chamber, whereby UV light that has passed through the UV transmission window in the UV irradiation chamber is irradiated onto the substrate, after which the auxiliary RF electrodes in the chamber are used to generate active species. A UV irradiation apparatus comprising a cleaning mechanism to efficiently implement such cleaning method is also provided. In an embodiment, this cleaning method may be combined with the conventional O₂+UV ozone cleaning. In another embodiment of the present invention, a more efficient cleaning method is presented, whereby cleaning gas that contains fluorine instead of or in addition to O₂ under the aforementioned method is used to generate active species through the auxiliary RF electrodes provided in the chamber. In such case, in an embodiment a material which offers a transmission ratio high enough not to let the light transmission window corrode due to fluorine is selected. For this material, CaF₂, MgF₂, BaF₂, Al₂O₃ or other crystal, or synthetic quartz coated with CaF₂, MgF₂, BaF₂ or Al₂O₃, can be used.

For purposes of summarizing aspects of the invention and the advantages achieved over the related art, certain objects and advantages of the invention are described in this disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description which follows.

### BRIEF DESCRIPTION OF THE DRAWINGS

These and other features of this invention will now be described with reference to the drawings of preferred embodiments which are intended to illustrate and not to limit the invention. The drawings are greatly simplified for illustrative purposes and are not necessarily to scale.

FIG. 1 is a schematic cross sectional view of a conventional UV irradiation apparatus.

FIG. 2 is a schematic cross sectional view of a reaction chamber of a UV irradiation apparatus according to an embodiment of the present invention.

FIG. 3 is a schematic cross sectional view of a reaction chamber of a UV irradiation apparatus according to another embodiment of the present invention.

FIG. 4 is a schematic cross sectional view of an upper part of a reaction chamber of a UV irradiation apparatus according to an embodiment of the present invention.

FIG. 5 is a schematic cross sectional view of an upper part of a reaction chamber of a UV irradiation apparatus according to another embodiment of the present invention.

FIG. 6 is a schematic cross sectional view of an upper part of a reaction chamber of a UV irradiation apparatus according to still another embodiment of the present invention.

FIG. 7 is a graph showing relationships between UV transmittance (%) and wavelength (nm) in examples.

FIG. 8 is a graph showing relationships between UV transmittance (%) and wavelength (nm) in other examples.

FIG. 9 is a schematic top cross sectional view of a gas ring used in examples.

FIG. 10 is a schematic cross sectional view of a conventional reaction chamber of a UV irradiation apparatus with a remote plasma unit.

### DETAILED DESCRIPTION OF EMBODIMENTS

In this disclosure, “gas” may include vaporized solid and/or liquid and may be constituted by a single gas or a mixture of gases. Gases can be supplied in sequence with or without overlap. In this disclosure, an article “a” refers to a species or a genus including multiple species. Further, in this disclosure, any two numbers of a variable can constitute a workable range of the variable as the workable range can be determined based on routine work, and any ranges indicated may include or exclude the endpoints. Additionally, any values of variables indicated may refer to precise values or approximate values and include equivalents, and may refer to average, median, representative, majority, etc. in some embodiments. In the present disclosure where conditions and/or structures are not specified, the skilled artisan in the art can readily provide such conditions and/or structures, in view of the present disclosure, as a matter of routine experimentation. In all of the disclosed embodiments, any element used in an embodiment can be replaced with any elements equivalent thereto, including those explicitly, necessarily, or inherently disclosed herein, for the intended purposes. Further, the present invention can equally be applied to apparatuses and methods. In this disclosure, any defined meanings do not necessarily exclude ordinary and customary meanings in some embodiments.

In the disclosure, “substantially zero” or the like may refer to an immaterial quantity, less than a detectable quantity, a quantity that does not materially affect the target or intended properties, or a quantity recognized by a skilled artisan as nearly zero, such that less than 10%, less than 5%, less than 1%, or any ranges thereof relative to the total in some embodiments.

Some embodiments of the present invention provide a UV irradiation apparatus for processing a semiconductor substrate, comprising: (i) a UV lamp unit for emitting UV light; (ii) a reaction chamber for processing the substrate with the UV light, said reaction chamber being provided with a susceptor for supporting the substrate thereon, said reaction chamber being disposed under the UV lamp unit; (iii) a gas ring with nozzles for supplying gas toward an axis of the gas ring, said UV lamp unit and said reaction chamber being connected via the gas ring, said gas ring serving as a first electrode; (iv) a transmission window through which UV light is transmitted from the UV lamp unit to the reaction chamber, said transmission window being supported by the gas ring and separating the interior of the UV lamp unit and the interior of the reaction chamber; (v) an RF shield which covers a surface of the transmission window facing the UV lamp unit; (vi) a second electrode disposed in the reaction chamber for generating a plasma between the first and second electrodes which are insulated from each other; and (vii) an RF power source for supplying RF power to one of the first or second electrode, the other of the first or second electrode being grounded.

By using the gas ring as the first electrode, in-situ plasma cleaning can effectively be performed in the vicinity of the nozzles of the gas ring where unwanted film tends to accumulate more than in other areas. Further, because the gas ring is circular, in-situ plasma cleaning can effectively be performed along the cylindrical inner wall of the reaction chamber. Further, because the transmission window is supported by the gas ring around the outer periphery, in-situ plasma cleaning can effectively be performed toward the center of the transmission window from the outer periphery. In some embodiments, in order to avoid supplying RF power to a gas supply line connected to the gas ring, the gas supply line is constituted by an insulation pipe. Further, the RF shield can effectively inhibit leakage of RF power through the transmission window, which may cause adverse effects on humans, noise in associated electronic appliances, incorrect operation, generation of heat, etc. In some embodiments, the RF shield is constituted by a large meshed net or grid having, e.g., an opening of about 20 mm formed by fine wires. In some embodiments, since multiple lamps and reflectors are used, light is diffused in all directions, a shadow cast by the meshed net or grid is negligible.

In some embodiments, the second electrode is embedded in a top portion of the susceptor, wherein the susceptor including the top portion is made of a non-conductive material such as a ceramic. RF power can be supplied to the second electrode from a bottom of the susceptor via a connector connected to the RF power, and thus, supplying RF power can be accomplished safely and easily.

In some embodiments, the second electrode is the susceptor, wherein portions of the susceptor other than a top portion for supporting the substrate thereon is covered by a non-conductive material such as a ceramic. The susceptor is made of a conductive material such as aluminum. In some embodiments, the non-conductive material is further covered by a conductive material, constituting an earth shield wherein the susceptor is connected to the RF power and is electronically floating.

In some embodiments, the second electrode is a circumferential portion of a wall of the reaction chamber, wherein the circumferential portion is insulated from other portions of the wall of the reaction chamber. When the RF power is connected to the first electrode (the gas ring), an RF supply plate is fixed to the gas ring, and a gas supply line connected to the gas ring is constituted by an insulation pipe so that RF power can be supplied to the gas ring stably without supplying RF power to the gas supply line. In some embodiments, the RF shield can also serve as the second electrode, so that in-situ plasma cleaning can more effectively be performed. In some embodiments, the RF power is connected to the second electrode (the circumferential portion of the wall). In some embodiments, the second electrode (the circumferential portion of the wall) is closer to the first electrode (the gas ring) than is the susceptor.

In some embodiments, the second electrode is a ring-shaped electrode disposed along a circumference of an inner wall of the reaction chamber, wherein the ring-shaped electrode is insulated from the inner wall of the reaction chamber. In the above embodiments, the ring-shaped electrode does not constitute the wall of the reaction chamber and can be installed on the inner wall of the reaction chamber. In some embodiments, the second electrode (the ring-shaped electrode) is closer to the first electrode (the gas ring) than is the susceptor. In some embodiments, the RF power is connected to the second electrode.

In some embodiments, the transmission window is constituted by a crystal of CaF₂, MgF₂, BaF₂, or Al₂O₃ or the transmission window is constituted by a synthetic quartz coated with CaF₂, MgF₂, BaF₂, or Al₂O₃. As compared with a SiO₂ material, the above material has higher resistance against plasma cleaning, so that when its surface is cleaned by plasma cleaning, over-etching of the surface can effectively be inhibited. When the surface is over-etched by plasma cleaning using, e.g., a fluorine-containing gas, UV transparency of the transmission window does not improve but is degraded.

In some embodiments, the gas ring is connected to an oxygen gas source. In some embodiments, the gas ring is connected to a fluorine-containing gas source.

In another aspect, some embodiments provide a method for cleaning any of the foregoing UV irradiation apparatuses, comprising: (a) after completion of UV irradiation by the UV lamp unit through the transmission window toward the substrate and removal of the substrate from the reaction chamber, supplying a cleaning gas to the reaction chamber through the nozzles of the gas ring; (b) applying RF power to the first or second electrode from the RF power source to generate a plasma of the cleaning gas between the first and second electrodes, thereby cleaning the gas ring, the transmission window, and an inner wall of the reaction chamber. Accordingly, in-situ plasma cleaning can effectively be performed.

The UV irradiation process can be any suitable processes including those disclosed in U.S. Pat. No. 6,759,098, U.S. Pat. No. 6,296,909, U.S. Pat. No. 6,583,048, U.S. Pat. No. 6,846,515, and U.S. Pat. No. 7,098,149, each disclosure disclosure of which is incorporated herein by reference in its entirety. Typically, the process may comprise processing a substrate (e.g., a semiconductor substrate) placed on a susceptor provided in a reaction chamber, by irradiating the substrate with UV light through an optical transmission window provided in the UV chamber between a UV light source and the susceptor.

In some embodiments, prior to the UV irradiation process, a film constituted by Si, C, H, O, and optionally N can be formed on the substrate by e.g., PECVD, PEALD, PVD, etc. In the above, the UV irradiation process may be a curing process of the film, decomposition of porogen, and/or removal of porogen. The UV irradiation process need not be limited to the curing process, and in an embodiment, the UV irradiation process is a photo CVD process.

The film includes, but is not limited to, a low dielectric film, a silicon carboxide film, or a dielectric film containing porogen. When the film formed on the substrate is cured in the reaction chamber or when the porogen is decomposed in and/or removed from the film on the substrate, the dielectric constant of the film is reduced, and when the film is cured, a significant amount of outgas is generated from the film as a result of decomposition of the chemical structures in the reaction chamber. The outgas may be composed of hydrocarbon species. The outgas accumulates on a surface of the inner wall of the reaction chamber including the optical transmission window. The deposit of the accumulated outgas interferes with UV light transmission through the optical transmission window, thereby decreasing efficiency of the process. Thus, particularly, the optical transmission window needs to be cleaned frequently.

In some embodiments, radical species of a cleaning gas is generated by a method other than UV irradiation, which uses RF electrodes. By UV irradiation, radical species of a cleaning gas can be generated, but it is difficult to obtain a sufficient amount of radical species, although it depends on the wavelength of light and the intensity of light. Thus, in some embodiments, in addition to application of RF power, UV irradiation through the transmission window is conducted so as to further excite the cleaning gas.

By controlling the pressure and flow in the reaction chamber, the cleaning process can be controlled. In some embodiments, the pressure may be 1,300 Pa or less (e.g., 50-1,200 Pa), a flow rate of oxygen gas may be 0.1-10 slm (e.g., 0.2-8 slm), a flow rate of inert gas such as Ar, He, Kr, or Xe may be 0.1-10 slm (e.g., 0.2-8 slm), and a cleaning time may be 5-1,000 sec (e.g., 10-600 sec, 50-400 sec). Preferably, in the above, UV irradiation is combined where UV light has an intensity of 1 mW/cm²-500 mW/cm² (e.g., 100 mW/cm²-400 mW/cm²) and a wavelength of 100-1000 nm (e.g., 150-400 nm).

In an embodiment, the cleaning gas may be a gas containing fluorine in a molecule such as NF₃, C₂F₆, and C₃F₈. Gas containing fluorine has high energy and can efficiently clean the optical transmission window. However, gas containing fluorine may damage the optical transmission window by corroding its surface. Normally, the optical transmission window is made of synthetic glass (silicon oxide), and the synthetic glass is apt to be etched by fluorine-containing gas. In a preferred embodiment, the optical transmission window may be constituted by a material which is resistant to fluorine-containing gas. In an embodiment, the optical transmission window may be constituted by a crystal of CaF₂, MgF₂, BaF₂, or Al₂O₃. In another embodiment, the optical transmission window may be constituted by a synthetic quartz coated with CaF₂, MgF₂, BaF₂, or Al₂O₃, CaF₂, for example, has a higher optical transmittance than SiO₂ and thus is preferred.

When a fluorine-containing gas is used as the cleaning gas, although UV irradiation can be performed in combination with RF power application, it need not be performed in the UV irradiation chamber in an embodiment. In an embodiment, the cleaning conditions may be as follows: The pressure may be 10 Torr or less (e.g., 0.2-8 Torr), a flow rate of fluorine-containing gas (e.g., NF₃) may be 0.1-10 slm (e.g., 0.2-2 slm), a flow rate of inert gas such as Ar, He, Kr, or Xe may be 0.1-10 slm (e.g., 0.2-2 slm), and a cleaning time may be 5-1000 sec (e.g., 10-600 sec, 50-400 sec).

In the above, as the cleaning gas, oxygen gas and fluorine-containing gas can be used in combination.

In some embodiments, the optical transmission window may have a diameter of 90% to 150% of that of a substrate (e.g., 100% to 130%) (e.g., 300 mm to 390 mm for a substrate having a diameter of 300 mm), and have a thickness of 10 mm to 30 mm (e.g., about 20 mm) which is sufficient to be used in a vacuum. In some embodiments, a distance between the optical transmission window and the substrate may be less than 400 mm (e.g., 5 mm to 350 mm).

In some embodiments, the present invention provides a method of semiconductor-processing by UV irradiation and cleaning a reaction chamber for semiconductor-processing, comprising the steps of: (i) processing a semiconductor substrate placed on a susceptor provided in a reaction chamber, by irradiating the substrate with UV light through an optical transmission window provided in the reaction chamber between a UV light source and the susceptor; and (ii) after completion of the processing step, generating radical species of a cleaning gas by RF electrodes installed inside the reaction chamber, thereby cleaning the optical transmission window and the inner wall of the reaction chamber. In the processing step, the UV light may have a wavelength of 100 nm to 1,000 nm (e.g., 150 nm to 400 nm).

The present invention will be explained with reference to drawings and preferred embodiments which are not intended to limit the present invention.

In the present disclosure where conditions and/or structures are not specified, the skilled artisan in the art can readily provide such conditions and/or structures, in view of the present disclosure, as a matter of routine experimentation.

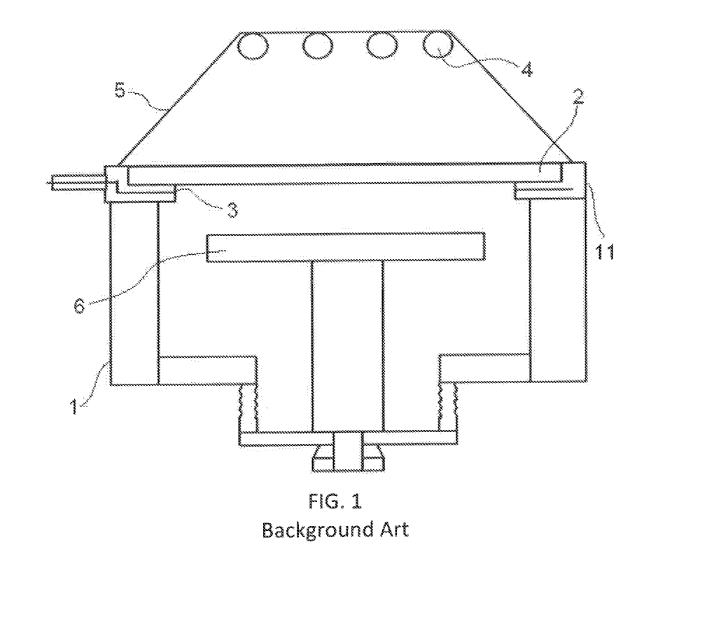

FIG. 1 is a schematic cross sectional view of a conventional UV irradiation apparatus. This apparatus comprises a chamber that can be controlled to a range of pressure conditions from vacuum to near atmospheric pressure, and a UV irradiation unit installed above the chamber. To be specific, this apparatus comprises a UV irradiation unit 5 including UV lamps 4, a transmission window 2, a gas ring (flange) 11 including gas introduction nozzles 3, a reaction chamber 1, a susceptor 6, and an exhaust port (not shown). It should be noted, however, that the apparatus need not conform to this figure as long as UV irradiation can be implemented.

In some embodiments, with regard to UV irradiation, the following structures and configurations can be employed: This UV irradiation apparatus has the UV lamp 4 that emits UV light continuously or in pulses, the susceptor 6 installed in parallel with and facing the aforementioned lamp, and the transmission window 2 installed in parallel with and facing the UV lamp 4 and susceptor 6 at a position between the two. The transmission window 2 is used to achieve uniform UV irradiation by shielding the reactor from atmosphere while transmitting UV light. As for the UV lamp 4 in the UV irradiation unit 5, multiple tubular lamps may be placed in parallel with one another, with the layout of these lamps arranged properly so as to achieve uniform illuminance, as shown in FIG. 1. A reflector may be provided to cause the UV light from each UV lamp to properly reflect onto the thin film (the reflector resembles an umbrella placed over the UV lamp), and the angle of the reflector may be made adjustable to achieve uniform illuminance.

In some embodiments, with regard to UV irradiation, the following structures and configurations also can be employed: The apparatus has a gas ring (flange) 11 in which the transmission window 2 is set, so as to separate the substrate processing part in the chamber 1 that can be controlled to a range of pressure conditions from vacuum to near atmospheric pressure, from the UV emission part that stores the UV lamps 4 emitting UV light continuously or in pulses. This flange 11 is connected to a gas introduction port and multiple gas discharge nozzles are provided in circumferential direction at specified intervals so that gas is discharged uniformly from points along the circumference toward the interior. To be specific, gas is introduced through the flange 11 and the multiple gas introduction nozzles are arranged symmetrically to create a uniform processing ambience. The UV lamp 4 is structured in such a way that it can be easily removed and replaced. The pressure in the substrate processing part is adjusted by a pressure control valve provided at an exhaust port. While the UV emission part is also a sealed space, it has an introduction port and discharge port (not illustrated) for purge gas (constantly purged by atmosphere, etc.).

Examples of the UV irradiation process are shown below. It should be noted, however, that the present invention is not at all limited to these embodiments. First, a gas selected from Ar, CO, CO₂, C₂H₄, CH₄, H₂, He, Kr, Ne, N₂, O₂, Xe, alcohol gases, and organic gases is introduced to the chamber 1 to create an ambience with a pressure between approx. 0.1 Torr and near atmosphere (including 1 Torr, 10 Torr, 50 Torr, 100 Torr, 1,000 Torr and any values between the foregoing numbers, preferably 1 to 50 Torr), and next a semiconductor substrate, which is the processing target, is transferred from a load lock chamber via a gate valve and placed on the susceptor 6 that has been set to a temperature between approx. 0° C. and approx. 650° C. (including 10° C., 50° C., 100° C., 200° C. 300° C., 400° C., 500° C., 600° C. and any values between the foregoing numbers, but preferably between 300° C. and 450° C.), after which UV light with a wavelength between approx. 100 nm and approx. 400 nm (including 150 nm, 200 nm, 250 nm, 300 nm, 350 nm and any values between the foregoing numbers, but preferably approx. 200 nm) and output between 1 mW/cm² and approx. 1,000 mW/cm² (including 10 mW/cm², 50 mW/cm², 100 mW/cm², 200 mW/cm², 500 mW/cm², 800 mW/cm² and any values between the foregoing numbers, preferably 5 to 200 mW/cm²) is irradiated at an appropriate distance (gap) (between 5 mm and 90 mm) from the UV lamps 4, onto the thin film on the semiconductor substrate either continuously or in pulses at a frequency between approx. 1 Hz and approx. 1,000 Hz (including 10 Hz, 100 Hz, 200 Hz, 500 Hz and any values between the foregoing numbers). The irradiation time is between approx. 1 sec and approx. 20 min (including 5 see, 10 sec, 20 sec, 50 sec, 100 sec, 200 sec, 500 sec, 1,000 sec and any values between the foregoing numbers). The gas in the chamber 1 is discharged from the exhaust port.

This semiconductor manufacturing apparatus carries out the above series of processing steps according to an automatic sequence, where the processing steps implemented include introduction of gas, irradiation of UV light, stopping of irradiation, and stopping of gas.

When outgas is generated from the thin film on the semiconductor substrate as a result of UV irradiation, substances constituting the outgas deposit on the transmission window made of synthetic quartz or the like, and also on the interior walls of the chamber. The contaminants deposited on the irradiation window absorb UV light and decrease the cure efficiency. The contaminants deposited on the interior walls of the chamber can produce particles as they separate from the walls.

Cleaning is performed to remove these contaminants. For example, cleaning is implemented by causing ozonization of O₂ using UV light and removing the contaminants by causing them to react with ozone. Since the percentage of O₂ ozonized by UV light is very low, in some embodiments of the present invention, O₂ is introduced into the reaction chamber, and is converted to radicals using RF electrodes and ozonized by UV light to increase the ozone production efficiency.

On the other hand, in cases where using ozone alone may not achieve sufficient cleaning when the film to be cured generates deposits that cannot be broken down by ozone, or a large amount of deposits, NF₃ can be used as the cleaning gas in some embodiments of the present invention. To be specific, NF₃ is introduced to the chamber to break down and remove the contaminants on the transmission window and interior chamber walls. However, these fluorine radicals, although having the effect of breaking down and removing the contaminants in the reaction chamber, also cause the adverse effect of eroding the surface of the transmission window made of synthetic quartz and thereby reducing the UV transmittance. Thus, in some embodiments, the optical transmission window is constituted by a crystal of CaF₂, MgF₂, BaF₂, or Al₂O₃, or by a synthetic quartz coated with CaF₂, MgF₂, BaF₂, or Al₂O₃. In some embodiments, a cleaning gas consists essentially of or consists of oxygen as an active cleaning gas (other than inactive gas such as rare gas), and the transmission window can be constituted sufficiently by a crystal of SiO₂.

In an aspect of the present invention, in combination with the UV irradiation, RF power is used to clean the inside the reaction chamber.

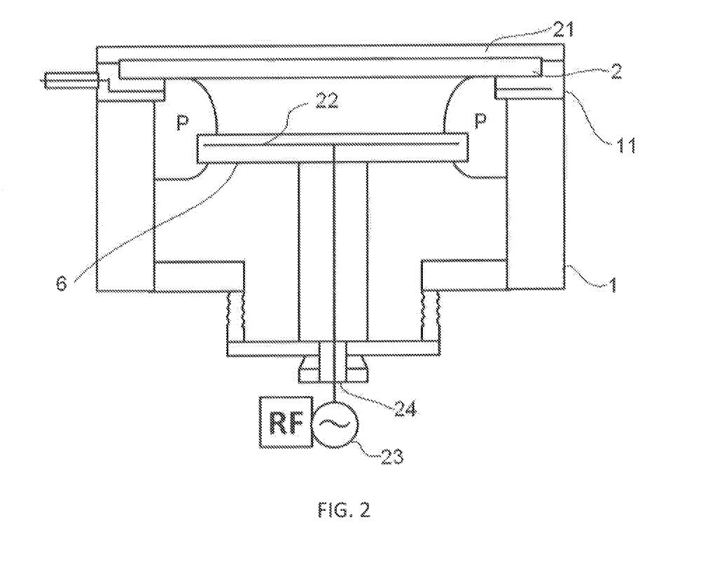

FIG. 2 is a schematic cross sectional view of a reaction chamber of a UV irradiation apparatus according to an embodiment of the present invention. The UV irradiation unit is omitted from this figure but can be any suitable unit including any of the foregoing UV irradiation units such as that illustrated in FIG. 1.

The apparatus illustrated in FIG. 2 has structures where an electrode 22 made of metal is embedded in a susceptor 6 made of ceramic (or other non-conductive materials) and serves as an RF electrode. RF power can safely be supplied from an RF power source 23 to the electrode 22 via a connector 24 located at a bottom of the susceptor and insulated from the reaction chamber 1. A gas ring 11 serves as a grounding electrode, thereby generating a plasma P between the electrodes. It should be noted that in this figure (also other figures), plasma P is shown only in exclusive areas for illustrative purposes where activated species are more present (higher concentration of plasma), but a plasma spreads and can reach the surface of the transmission window and the surface of the inner wall of the reaction chamber where deposits accumulate. A transmission window 2 is supported by the gas ring 11, and an RF shield 21 is placed on top of the transmission window 2.

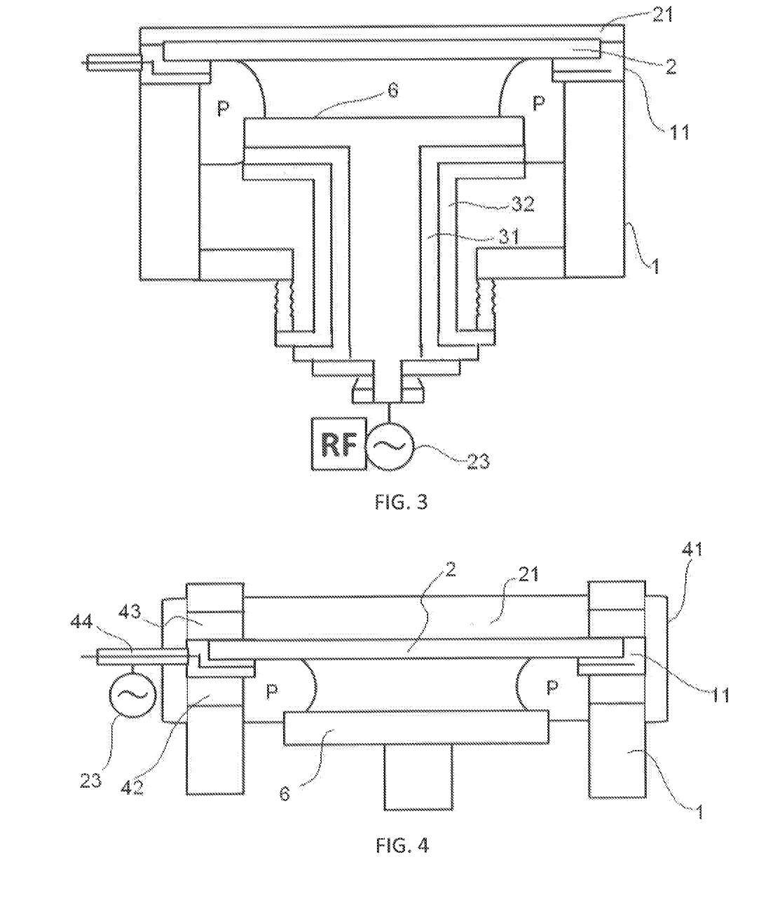

FIG. 3 is a schematic cross sectional view of a reaction chamber of a UV irradiation apparatus according to another embodiment of the present invention. The UV irradiation unit is omitted from this figure but can be any suitable unit including any of the foregoing UV irradiation units such as that illustrated in FIG. 1.

The apparatus illustrated in FIG. 3 has structures where a susceptor 6 is made of aluminum, and an earth shield is arranged around the susceptor 6 except for a top portion. In order to fix the susceptor at its bottom while making the susceptor in an electronically floating state, a sheet 31 of Al₂O₃ (or other non-conductive materials) having a thickness of about 10 mm, and a sheet 32 of Al (or other conductive materials) having a thickness of about 10 mm cover the susceptor 6. The susceptor itself serves as an electrode and is connected to an RF power source 23.

FIG. 4 is a schematic cross sectional view of an upper part of a reaction chamber of a UV irradiation apparatus according to an embodiment of the present invention. The UV irradiation unit is omitted from this drawing but can be any suitable unit including any of the foregoing UV irradiation units such as that illustrated in FIG. 1. Also, a lower part of the susceptor 6 and a lower part of the reaction chamber 1 are omitted from this drawing but can be any suitable structures such as those illustrated in FIGS. 2 and 3.

The apparatus illustrated in FIG. 4 has structures where a ring-shaped insulation plate 42 of Al₂O₃ (or other non-conductive materials) having a thickness of about 10 mm and a width of about 30 mm is placed via an O-ring on top of a wall of the reaction chamber 1 having a groove for an O-ring, and a gas ring 11 having an O-ring groove on its lower surface is placed via an O-ring on top of the ring-shaped insulation plate 42, and a ring-shaped insulation plate 43 of Al₂O₃ (or other non-conductive materials) having a thickness of about 10 mm and a width of about 30 mm is placed via an O-ring on top of the gas ring 11. An RF application plate (not shown) is fixed to the gas ring 11 using threads, and a gas supply line connected to the gas ring 11 near an RF cover 41 is constituted by an insulation pipe 44, so that RF power is not applied to the gas supply line. The RF power source 23 is connected to the gas ring 11 which serves as a powered electrode. The RF cover 41 covers an outer periphery of the laminate of the ring-shaped insulation plate 41, the gas ring 11, and the ring-shaped insulation plate 42. Further, the RF shield 21 is also conductively connected to the wall of the reaction chamber 1, so that both the RF shield and the wall of the reaction chamber serve as a grounding electrode wherein a plasma more easily reaches the entire surface of the transmission window 2 as compared with other embodiments.

FIG. 5 is a schematic cross sectional view of an upper part of a reaction chamber of a UV irradiation apparatus according to another embodiment of the present invention. The UV irradiation unit is omitted from this drawing but can be any suitable unit including any of the foregoing UV irradiation units such as that illustrated in FIG. 1. Also, a lower part of the susceptor 6 and a lower part of the reaction chamber 1 are omitted from this drawing but can be any suitable structures such as those illustrated in FIGS. 2 and 3.

The apparatus illustrated in FIG. 5 has structures where a ring-shaped insulation plate 52 of Al₂O₃ (or other non-conductive materials) having a thickness of about 10 mm and a width of about 30 mm is placed via an O-ring on top of a wall of the reaction chamber 1 having a groove for an O-ring, and a ring-shaped conductive plate 53 of Al (or other conductive materials) having a thickness of about 20 mm and a width of about 30 mm and having an O-ring groove on its lower and upper surfaces is placed via an O-ring on top of the ring-shaped insulation plate 52, and a ring-shaped insulation plate 54 of Al₂O₃ (or other non-conductive materials) having a thickness of about 10 mm and a width of about 30 mm is placed via an O-ring on top of the ring-shaped conductive plate 53. Further, a gas ring 11 having an O-ring groove on its lower surface is placed via an O-ring on top of the ring-shaped insulation plate 54. An RF application plate (not shown) is fixed to the ring-shaped conductive plate 53 using threads, and an RF cover 51 covers an outer periphery of the laminate of the ring-shaped insulation plate 52, the ring-shaped conductive plate 53, the ring-shaped insulation plate 54, and the gas ring 11. The RF power source 23 is connected to the ring-shaped conductive plate 53, and the ring-shaped conductive plate 53 serves as a powered electrode while the gas ring 11 serves as a grounding electrode.

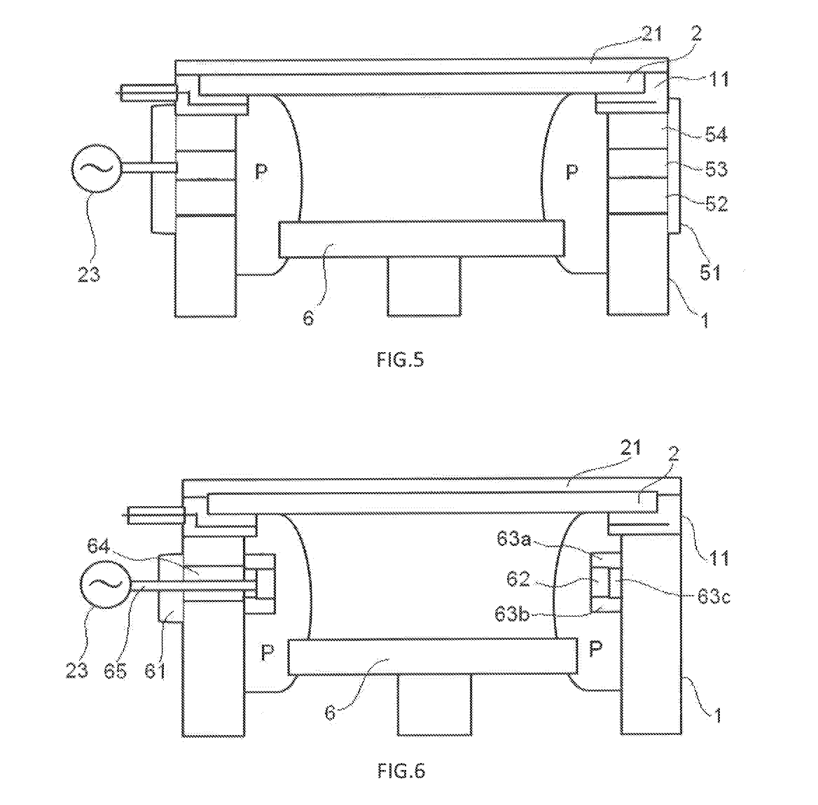

FIG. 6 is a schematic cross sectional view of an upper part of a reaction chamber of a UV irradiation apparatus according to still another embodiment of the present invention. The UV irradiation unit is omitted from this drawing but can be any suitable unit including any of the foregoing UV irradiation units such as that illustrated in FIG. 1. Also, a lower part of the susceptor 6 and a lower part of the reaction chamber 1 are omitted from this drawing but can be any suitable structures such as those illustrated in FIGS. 2 and 3.

The apparatus illustrated in FIG. 6 has structures where a ring-shaped conductive plate 62 of Al (or other conductive materials) having a thickness of about 20 mm and a width of about 10 mm is surrounded along its outer periphery by a ring-shaped insulation plate 63c of Al₂O₃ (or other non-conductive materials) having a thickness of about 20 mm and a width of about 10 mm (the outer periphery of the plate 62 is in contact with the inner periphery of the plate 63c), and both plates 62, 63c are sandwiched by a ring-shaped insulation upper plate 63a of Al₂O₃ (or other non-conductive materials) having a thickness of about 10 mm and a width of about 20 mm and a ring-shaped insulation lower plate 63b of Al₂O₃ (or other non-conductive materials) having a thickness of about 10 mm and a width of about 20 mm. The ring-shaped conductive plate 62 is connected to the RF power source 23 via an RF terminal 65 through the wall of the reaction chamber 1 where an insulation material 64 encloses the RF terminal 65 and is covered by an RF cover 61. The above integrated rings are disposed about 10 mm below the gas ring 11 and fixed to the inner wall of the reaction chamber using a stopper (not shown). The ring-shaped conductive plate 62 serves as a powered electrode while the gas ring 11 serves as a grounding electrode.

In some embodiments, in-situ plasma cleaning may be performed under the following conditions:
Pressure: 0.1 to 10 Torr (typically 0.2 to 8 Torr)
Temperature: 0 to 650° C. (typically 300 to 450° C.)
Cleaning gas: oxygen gas and/or fluorine-containing gas
Distance between the electrodes: less than 400 mm (typically 5 to 350 mm)
RF frequency: 0.2 to 60 MHz (typically 2 to 30 MHz)
RF power: 0.1 to 4 W/cm² (typically 0.2 to 2 W/cm² (wattage per area of susceptor top surface); 100 to 4,000 W, typically 200 to 2,000 W, per 1,000 cm² of the susceptor top surface)
Cleaning duration: 0.2 to 30 minutes (typically 0.5 to 10 minutes)

### EXAMPLES

### Example 1

A substrate (300 mm in diameter) having a dielectric film containing a porogen material formed thereon was loaded in a UV irradiation apparatus illustrated in FIG. 2 provided with a transmission window made of synthetic quartz (SiO₂) having a thickness of 20 mm. The dielectric film formed on the substrate was cured in the apparatus under the following conditions:
Pressure: 1-50 Torr
Supplied gas: Nitrogen gas
Temperature: 300-450° C.
Distance between the substrate and the lamps: 5-350 mm
UV wavelength: 150-400 nm
Illuminance (output or intensity) of UV lamps: 5-200 W/cm²
Irradiation duration: 60 to 600 seconds

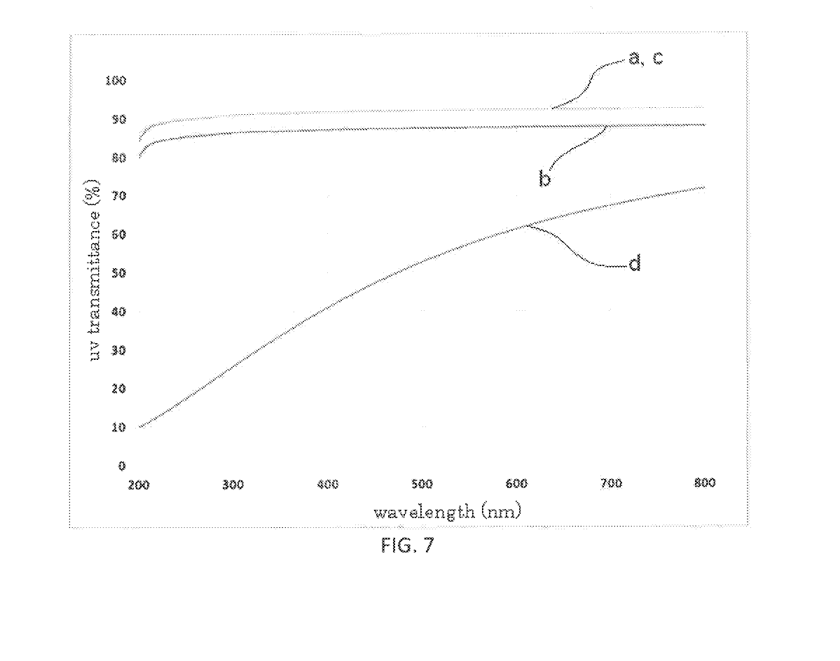

UV transmittance (%) of the transmission window (“a” in FIG. 7) was measured using a spectrophotometer prior to the curing. After 20 substrates were cured, UV transmittance (%) of the transmission window (“b” in FIG. 7) was again measured using a spectrophotometer.

Next, the reaction chamber was subjected to cleaning. The cleaning conditions were as follows:
Cleaning gas: NF₃ or O₂
Chamber pressure: 1-10 Torr
Cleaning gas flow rate: 0.5-2 slm for NF₃; 0.2-8 slm for O₂
Ar gas flow rate: 2-5 slm for NF₃ (for stabilizing a plasma); none for O₂
RF power (13.56 MHz): 500 W
Cleaning duration: 5 minutes

After the cleaning, UV transmittance (%) of the transmission window (“c” for cleaning gas O₂, “d” for cleaning gas NF₃ in FIG. 7) was again measured using a spectrophotometer. The results are shown in FIG. 7 which is a graph showing the relationships between UV transmittance (%) and wavelength (nm). As shown in FIG. 7, after the UV curing. UV transmittance of the transmission window decreased (“b”) as compared with the initial UV transmittance of the transmission window (“a”) regardless of the wavelength of UV light. When the cleaning gas was O₂, UV transmittance was recovered substantially to the initial degree by the cleaning (“c”). However, when the cleaning gas was NF₃, UV transmittance was drastically reduced (e.g. a reduction of 50% at 400 nm) (“d”), indicating that corrosion of the transmission window surface by radicals of NF3 occurred. By visual inspection, roughness and cloudiness were observed on the surface of the transmission window when the cleaning gas was NF₃. Thus, when oxygen is used as a cleaning gas, in-situ plasma cleaning can effectively clean the surface of a transmission window.

### Example 2

The same tests as in Example 1 were conducted except that the transmission window made of synthetic quartz was coated by a layer of Al₂O₃ having a thickness of 300 nm.

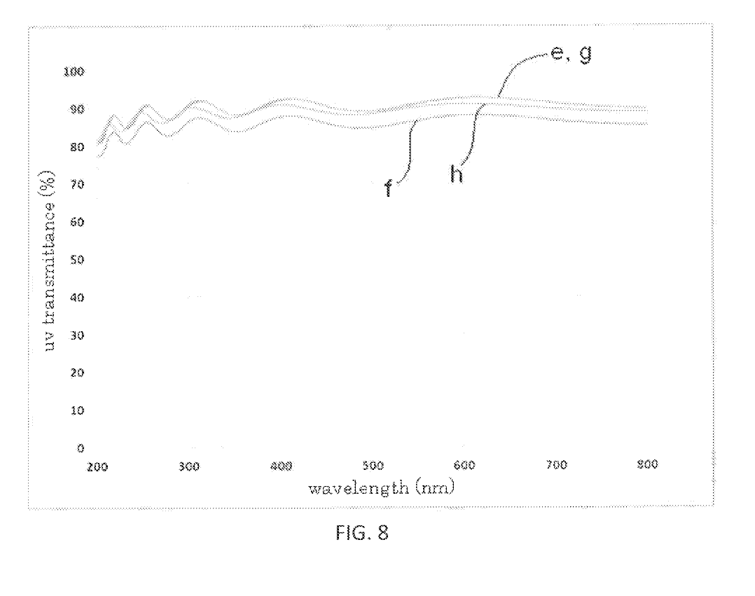

The results are shown in FIG. 8 which is a graph showing the relationships between UV transmittance (%) and wavelength (nm). As shown in FIG. 8, after the UV curing, UV transmittance of the transmission window decreased (“f”) as compared with the initial UV transmittance of the transmission window (“e”) regardless of the wavelength of UV light. When the cleaning gas was O₂, UV transmittance was recovered substantially to the initial degree by the cleaning (“f”). Also when the cleaning gas was NF₃, UV transmittance was recovered almost to the initial degree by the cleaning (“h”). By visual inspection, no roughness or cloudiness was observed on the surface of the transmission window when the cleaning gas was NF₃. Thus, when the surface of the transmission window coated with Al₂O₃ has resistance against corrosion by fluorine, cleaning effect by radicals of NF3 improves.

### Example 3

For evaluating cleaning rate, three wafer coupons were attached to a lower surface of a gas ring at positions illustrated in FIG. 9 which is a schematic top cross sectional view of the gas ring, wherein numbers in circles are coupon numbers (the coupon numbers are indicated on the gas ring for illustrative purposes, and the coupons were attached on a lower surface of the gas ring which is not shown in FIG. 9). The gas ring 11 included a circular gas channel 91 provided with a gas inlet port 90 and having gas nozzles 92 extending from the circular gas channel in a radical direction toward the center. Coupon No. 3 was attached near an exhaust, and coupon No. 1 was attached opposite to coupon No. 3. Coupon No. 2 was attached between coupon No. 1 and No. 3. The coupon had a film constituted by Si, O, C, and H, and by cleaning, carbon in the film was removed from the film, thereby reducing the thickness of the film. When the reduction degree of the film thickness was high, the content of carbon removed from the film was considered to be high, meaning that etching rate was high; i.e., cleaning seed was determined to be high.

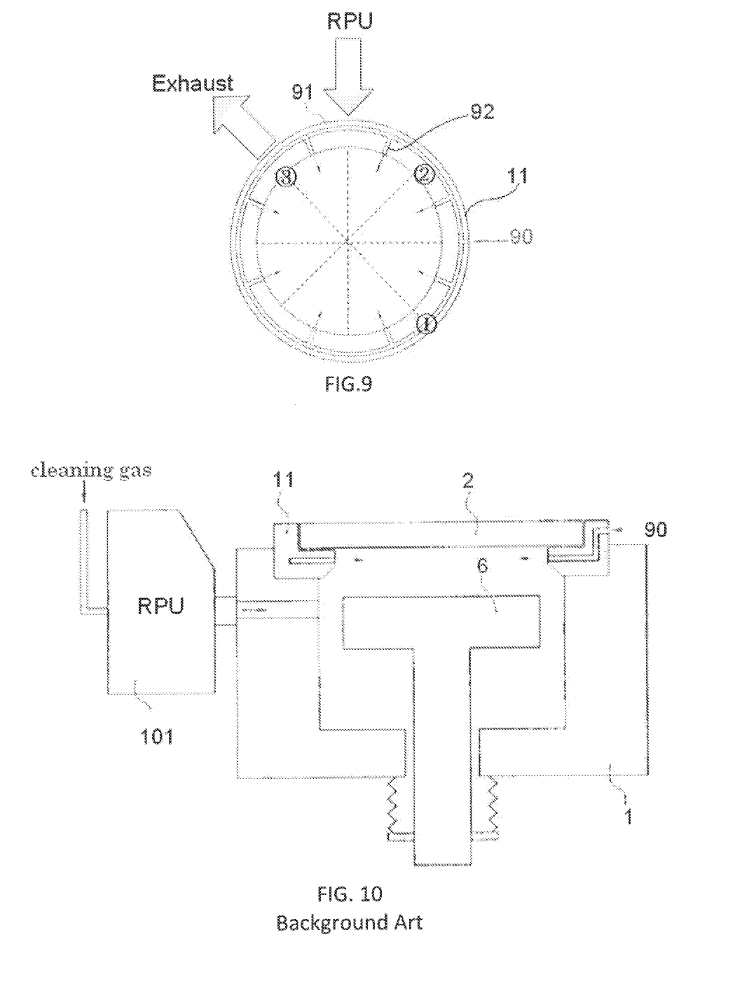

The gas ring of each of UV irradiation apparatuses illustrated in FIGS. 2 to 6 was provided with wafer coupons as described above, and as a comparative example, the gas ring of a UV irradiation apparatus with a remote plasma unit (RPU) as illustrated in FIG. 10 was also provided with wafer coupons as described above. FIG. 10 is a schematic cross sectional view of the reaction chamber of the UV irradiation apparatus with the remote plasma unit wherein the remote plasma unit 101 was attached to the reaction chamber 1 provided with the susceptor 6 and the transmission window 2 supported by the gas ring 11 having the gas inlet port 90. Excited gas from the remote plasma unit was introduced from the direction indicated by “RPU” in FIG. 9. Each reaction chamber was subjected to cleaning. The cleaning conditions were as follows:

Remote Plasma:
Cleaning gas: O₂
Chamber pressure: 800 Pa
Cleaning gas flow rate: 6 slm
Ar gas flow rate: 6 slm
Cleaning duration: 1 minutes

In-situ Plasma:
Cleaning gas: O₂
Chamber pressure: 200 Pa
Cleaning gas flow rate: 6 slm
RF power (13.56 MHz): 500 W
Cleaning duration: 2 minutes

The etching rate (nm/min) of each coupon was measured after the cleaning. The results are shown in Table 1 below. Examples 3-1 to 3-5 represent UV irradiation apparatuses illustrated in FIGS. 2 to 6, respectively.

TABLE 1
Etching rate (nm/min)

| Coupon | Remote | | | | | |
|---|---|---|---|---|---|---|
| No. | plasma | Ex. 3-1 | Ex. 3-2 | Ex. 3-3 | Ex. 3-4 | Ex. 3-5 |
| 1 | 62 | 156 | 131 | 145 | 122 | 139 |
| 2 | 15 | 143 | 114 | 132 | 107 | 125 |
| 3 | 131 | 215 | 196 | 202 | 177 | 199 |

As shown in Table 1, by in-situ plasma cleaning using the gas ring and another part of the reaction chamber as electrodes, cleaning was more effectively and more uniformly performed as compared with remote plasma cleaning.

The present invention includes the above mentioned embodiments and other various embodiments including the following:

1) A step to clean the UV light transmission window and inner walls of the UV irradiation chamber, provided as a cleaning method for a UV irradiation chamber, whereby UV light that has passed through the UV transmission window in the UV irradiation chamber is irradiated onto the substrate, after which auxiliary RF electrodes in the chamber are used to generate active species.

2) A method according to 1), wherein the cleaning gas is oxygen gas.

3) A method according to 2), also including a step to irradiate the active species using the UV light through the UV light transmission window to excite the active species further.

4) A method according to 1), wherein the cleaning gas contains fluorine in its molecule.

5) A method according to 4), wherein the UV light transmission window is constituted by a crystal of CaF₂, MgF₂, BaF₂ or Al₂O₃.

6) A method according to 4), wherein the UV light transmission window is constituted by a synthetic quartz coated with CaF₂, MgF₂, BaF₂ or Al₂O₃.

7) A method for cleaning the UV irradiation chamber for semiconductor-processing while semiconductor-processing is performed by UV irradiation, wherein said method is characterized in that it includes: a step to process the semiconductor substrate placed on a susceptor provided in the UV irradiation chamber, by irradiating the substrate with UV light through the UV light transmission window provided between a UV light source and the susceptor in the UV irradiation chamber; and a step to clean the UV light transmission window and inner walls of the UV irradiation chamber by generating active species, after the completion of the aforementioned processing step, using the auxiliary RF electrodes provided in the chamber.

8) A method according to 7), wherein the UV light has a wavelength of 150 nm to 400 nm.

9) A method according to 7), wherein semiconductor substrates on which low dielectric film, SiOC film or porogen-containing dielectric film are formed are processed in the processing step.

10) A method according to 7), wherein the cleaning gas is oxygen gas.

11) A method according to 10), wherein another step is provided to irradiate the active species using UV light through the UV light transmission window to excite the active species further.

12) A method according to 7), wherein the cleaning gas contains fluorine in its molecule.

13) A method according to 12), wherein the substrate is irradiated through the UV light transmission window constituted by a crystal of CaF₂, MgF₂, BaF₂ or Al₂O₃ in the processing step.

14) A method according to 12), wherein the substrate is irradiated through the UV light transmission window constituted by a synthetic quartz coated with CaF₂, MgF₂, BaF₂ or Al₂O₃ in the processing step.

It will be understood by those of skill in the art that numerous and various modifications can be made without departing from the spirit of the present invention. Therefore, it should be clearly understood that the forms of the present invention are illustrative only and are not intended to limit the scope of the present invention.

We/I claim:

1. A UV irradiation apparatus for processing a semiconductor substrate, comprising:
a UV lamp unit for emitting UV light;
a reaction chamber for processing the substrate with the UV light, said reaction chamber being provided with a susceptor for supporting the substrate thereon, said reaction chamber being disposed under the UV lamp unit;
a gas ring with nozzles for supplying gas toward an axis of the gas ring, said UV lamp unit and said reaction chamber being connected via the gas ring, said gas ring serving as a first electrode;
a transmission window through which UV light is transmitted from the UV lamp unit to the reaction chamber, said transmission window being supported by the gas ring and separating the interior of the UV lamp unit and the interior of the reaction chamber;
an RF shield which covers a surface of the transmission window facing the UV lamp unit;
a second electrode disposed in the reaction chamber for generating a plasma between the first and second electrodes which are insulated from each other; and
an RF power source for supplying RF power to one of the first or second electrode, the other of the first or second electrode being grounded.

2. The UV irradiation apparatus according to claim 1, wherein the second electrode is embedded in a top portion of the susceptor, wherein the susceptor including the top portion is made of a non-conductive material.

3. The UV irradiation apparatus according to claim 2, wherein the RF power is connected to the second electrode.

4. The UV irradiation apparatus according to claim 1, wherein the second electrode is the susceptor, wherein portions of the susceptor other than a top portion for supporting the substrate thereon is covered by a non-conductive material.

5. The UV irradiation apparatus according to claim 4, wherein the insulating material is a ceramic.

6. The UV irradiation apparatus according to claim 4, wherein the RF power is connected to the second electrode.

7. The UV irradiation apparatus according to claim 1, wherein the second electrode is a circumferential portion of a wall of the reaction chamber, wherein the circumferential portion is insulated from other portions of the wall of the reaction chamber.

8. The UV irradiation apparatus according to claim 7, wherein the RF power is connected to the first electrode.

9. The UV irradiation apparatus according to claim 7, wherein the RF power is connected to the second electrode.

10. The UV irradiation apparatus according to claim 1, wherein the second electrode is a ring-shaped electrode disposed along a circumference of an inner wall of the reaction chamber, wherein the ring-shaped electrode is insulated from the inner wall of the reaction chamber.

11. The UV irradiation apparatus according to claim 10, wherein the RF power is connected to the second electrode.

12. The UV irradiation apparatus according to claim 1, wherein the transmission window is constituted by a crystal of CaF₂, MgF₂, BaF₂, or Al₂O₃.

13. The UV irradiation apparatus according to claim 1, wherein the transmission window is constituted by a synthetic quartz coated with CaF₂, MgF₂, BaF₂, or Al₂O₃.

14. The UV irradiation apparatus according to claim 1, wherein the gas ring is connected to an oxygen gas source.

15. The UV irradiation apparatus according to claim 1, wherein the gas ring is connected to a fluorine-containing gas source.

16. A method for cleaning the UV irradiation apparatus of claim 1, comprising:
after completion of UV irradiation by the UV lamp unit through the transmission window toward the substrate and removal of the substrate from the reaction chamber, supplying a cleaning gas to the reaction chamber through the nozzles of the gas ring;
applying RF power to the first or second electrode, from the RF power source, to generate a plasma of the cleaning gas between the first and second electrodes, thereby cleaning the gas ring, the transmission window, and an inner wall of the reaction chamber.

17. The method according to claim 16, wherein the cleaning gas is oxygen.

18. The method according to claim 16, wherein the cleaning gas contains fluorine.

19. The method according to claim 18, wherein the transmission window is constituted by a crystal of CaF₂, MgF₂, BaF₂, or Al₂O₃.

20. The method according to claim 18, wherein the transmission window is constituted by a synthetic quartz coated with CaF₂, MgF₂, BaF₂, or Al₂O₃.
